(19) United States
(12) Patent Application Publication
(10) Pub. No.: US 2021/0359043 A1
(43) Pub. Date: Nov. 18, 2021

(54) ARRAY SUBSTRATE AND MANUFACTURING METHOD THEREOF, AND DISPLAY DEVICE

(71) Applicant: WUHAN CHINA STAR OPTOELECTRONICS SEMICONDUCTOR DISPLAY TECHNOLOGY CO., LTD., WUHAN (CN)

(72) Inventors: LIANG FANG, WUHAN (CN); DING DING, WUHAN (CN)

(21) Appl. No.: 16/614,422

(22) PCT Filed: Oct. 15, 2019
(86) PCT No.: PCT/CN2019/111156

§ 371 Date: Nov. 18, 2019

(30) Foreign Application Priority Data
Jun. 25, 2019 (CN) 201910552123.9

(51) Int. Cl. H01L 27/32

(52) U.S. Cl. CPC H01L 27/3246; H01L 2227/323

(57) ABSTRACT

An array substrate and a manufacturing method thereof, and a display device are provided. On one hand, the present disclosure is facilitated to improve abnormal phenomena such as voltage drop, brightness unevenness of light emitting, on the other hand, by reducing a photomask of a process for a planarization layer, the present disclosure prevents an abnormal phenomenon of film peeling during covering the top planarization layer after the bottom planarization layer is etched at a large area, thereby improving reliability of the display device.

### FIELD OF INVENTION

The present disclosure relates to the field of display technology, and specifically relates to an array substrate and manufacturing method thereof, and display device.

### BACKGROUND OF INVENTION

Organic light emitting diode (OLED) display devices are also known as organic electroluminesence display devices or organic light emitting semiconductors. The working principle of OLEDs is that when the power is supplied to an appropriate voltage, positive holes and cathode charges are combined in a light emitting layer, and under Coulomb force, they are combined to form excitons (electron-hole pairs) in an excited state at a certain probability, and the excited state is unstable in a general environment. The excitons in the excited state recombine and transfer energy to a luminescent material, causing it to jump from the ground state to the excited state, and the energy in excited state generates photons through the radiation relaxation process to release light energy and produce light, and according to the different formula of the luminescent material, it can produce three primary (RGB) colors of red, green and blue to form the basic colors.

OLEDs have advantages such as low voltage demand, high power saving efficiency, rapid response, light weight, thin thickness, simple structure, low cost, wide visual angle, almost infinite contrast, low power consumption and ultimate rapid reaction speed, and have become one of the most important display technologies today.

A mainstream of a driving method for driving OLEDs is current driving. A driving current is input to a display device on a lower bezel by a source/drain (SD) electrode. Because a certain resistance exists on the source/drain electrode itself, voltage drop (IR drop) exists during signal transmission, that is, the voltage close to a top bezel is small. The brightness of the display device is related to a driving voltage on the source/drain electrode, which eventually causes abnormal brightness unevenness to occur on the display device. Presently, a method for solving the brightness unevenness of the OLED display devices is a two-layer source/drain electrode structure, that is, adopting two planarization layers to realize a connection between a first source/drain electrode layer and a second source/drain electrode layer, and a connection between the second source/drain electrode layer and a pixel electrode layer respectively. During etching the source/drain electrode layer, the bottom planarization layer will be etched at a large area, so that abnormal of film peeling off will easily occur when covering the top planarization layer after then. Therefore, it is necessary to seek a new type of a display device to solve the problems mentioned above.

### SUMMARY OF INVENTION

One purpose of the present disclosure is to provide an array substrate and a manufacturing method thereof, and a display device, which can reduce a photomask of a process for a planarization layer, and improves a phenomenon of film peeling during covering the top planarization layer after the bottom planarization layer is etched at a large area, thereby improving reliability of the display device.

In order to solve the problems mentioned above, an embodiment of the present disclosure provides an array substrate which defines a display region and a bending region and includes a substrate, a buffer layer, an active layer, and a first source/drain electrode layer. Furthermore, the buffer layer is disposed on the substrate; the active layer is disposed on the buffer layer of the display region, and the active layer includes a host section and two lateral sections; the first source/drain electrode layer includes a first source electrode and a first drain electrode, the first source electrode and the first drain electrode respectively overlap on the two lateral sections of the active layer.

Furthermore, the array substrate further includes an insulation layer, a gate electrode layer, an interlayer insulation layer, and a second source/drain electrode layer. Furthermore, the insulation layer is disposed on the first source/drain electrode layer; the gate electrode layer is disposed on the insulation layer; the interlayer insulation layer is disposed on the gate electrode layer; the second source/drain electrode layer is disposed on the interlayer insulation layer, and the second source/drain electrode layer is connected to the first source/drain electrode layer by a first contact hole.

Furthermore, an organic photoresist layer is disposed on the substrate of the bending region, and the second source/drain electrode layer is disposed on the organic photoresist layer.

Furthermore, the insulation layer includes a first insulation layer and a second insulation layer; the gate electrode layer includes a first gate electrode layer and a second gate electrode layer; the first insulation layer is disposed on the active layer; the first gate electrode layer is disposed on the first insulation layer; the second insulation layer is disposed on the first gate electrode layer; the second gate electrode layer is disposed on the second insulation layer; the interlayer insulation layer is disposed on the second gate electrode layer.

Furthermore, the second source/drain electrode layer is configured to be a reticular structure.

Another embodiment of the present disclosure further provides a manufacturing method of the array substrate related by the present disclosure, which includes steps as follow: S1, making the array substrate to be manufactured define the display region and the bending region, providing the substrate, and forming the buffer layer on the substrate; S2, depositing the active layer on the buffer layer; S3, utilizing excimer laser crystallization technology to realize polysiliconization of the active layer, and using the photoresist (PR) photomask to make the active layer be patterned, doping ions to the active layer by one PR photomask to form the host section and the two lateral sections; S4, depositing the first source/drain electrode layer on the active layer, and using a photoresist (PR) photomask to realize patterning on the first source/drain electrode layer; etching all of the first source/drain electrode layer of the bending region to obtain the first source electrode and the first drain electrode; and making the first source electrode and the first drain electrode overlap on two lateral sections of the active layer.

Furthermore, the manufacturing method further includes the steps as follow: S5, depositing an insulation layer on the first source/drain electrode layer, and depositing a gate electrode layer on the insulation layer; S6, depositing and manufacturing an interlayer insulation layer on the gate electrode layer; S7, depositing and manufacturing a second source/drain electrode layer on the interlayer insulation layer, and the second source/drain electrode layer connected to the first source/drain electrode layer by a first contact hole.

Furthermore, S7 further includes: etching from a surface of the interlayer insulation layer of the bending region away from the substrate till a surface of the substrate toward the interlayer insulation layer by PR photomask technology to form a groove, and filling organic photoresist material in the groove to form an organic photoresist layer; depositing the second source/drain electrode layer on the organic photoresist layer.

Another embodiment of the present disclosure further provides a display device. The display device includes a display panel. The display panel includes the array substrate related by the present disclosure.

Furthermore, the display panel further includes a planarization layer, a pixel electrode layer, and a pixel definition layer.

Furthermore, the planarization layer is disposed on the interlayer insulation layer and the organic photoresist layer; the pixel electrode layer is disposed on the planarization layer of the display region, and the pixel electrode layer is connected on the second source/drain electrode layer by a second contact hole; the pixel definition layer is disposed on the planarization layer on both sides of the pixel electrode layer.

The present disclosure relates to an array substrate and a manufacturing method thereof, and a display device. On one hand, the present disclosure is facilitated to improve abnormal phenomena such as voltage drop, brightness unevenness of light emitting, on the other hand, by reducing a photomask of a process for a planarization layer, the present disclosure prevents a phenomenon of film peeling during covering the top planarization layer after the bottom planarization layer is etched at a large area, thereby improving reliability of the display device.

### DESCRIPTION OF DRAWINGS

To more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further figures without making any inventive efforts.

FIG. 1 is a structural schematic diagram of a display panel of a display device of the present disclosure.

FIG. 2 is a first manufacturing schematic diagram of the display panel of the display device of the present disclosure.

FIG. 3 is a second manufacturing schematic diagram of the display panel of the display device of the present disclosure.

FIG. 4 is a third manufacturing schematic diagram of the display panel of the display device of the present disclosure.

FIG. 5 is a fourth manufacturing schematic diagram of the display panel of the display device of the present disclosure.

FIG. 6 is a fifth manufacturing schematic diagram of the display panel of the display device of the present disclosure.

FIG. 7 is a sixth manufacturing schematic diagram of the display panel of the display device of the present disclosure.

FIG. 8 is a seventh manufacturing schematic diagram of the display panel of the display device of the present disclosure.

FIG. 9 is an eighth manufacturing schematic diagram of the display panel of the display device of the present disclosure.

FIG. 10 is a ninth manufacturing schematic diagram of the display panel of the display device of the present disclosure.

FIG. 11 is a tenth manufacturing schematic diagram of the display panel of the display device of the present disclosure.

FIG. 12 is an eleventh manufacturing schematic diagram of the display panel of the display device of the present disclosure.

### DETAILED DESCRIPTION OF PREFERRED EMBODIMENTS

The preferred embodiments of the present disclosure are described in detail below with reference to the accompanying figures to completely introduce technical content of the present disclosure to those skilled in the art, and to give an example that the present disclosure can be implemented. This makes the technical content of the present disclosure will be clearer and those skilled in the art will more readily understand how to implement the present disclosure. However, the present disclosure can be implemented in many different forms of embodiments. The scope of the present disclosure is not limited to the embodiments mentioned herein, and the description of the embodiments below is not intended to limit the scope of the present disclosure.

The directional terms of which the present disclosure mentions, for example, “top”, “bottom”, “upper”, “lower”, “front”, “rear”, “left”, “right”, “inside”, “outside”, “side”, etc., are just refer to directions of the accompanying figures. The directional terms used herein are used to explain and describe the present disclosure, and are not intended to limit the scope of the present disclosure.

In the figures, components with similar structures are indicated by the same reference numerals, and components that have similar structure or function are indicated by the similar reference numerals. Moreover, for ease of understanding and description, the dimensions and thickness of each component shown in the accompanying figures are arbitrarily shown, and the present disclosure does not limit the dimensions and thickness of each component.

When a component is described as “on” another component, the component can be placed directly on the other component; there can also be an intermediate component, the component is placed on the intermediate component, and the intermediate component is placed on another component. When a component is described as “mounted” or “connected to” another component, it can be understood as “directly mounted” or “directly connected to”, or a component is “mounted” or “connected to” through an intermediate component to another component.

### The First Embodiment

This embodiment provides a display device, the display device includes a display panel 100.

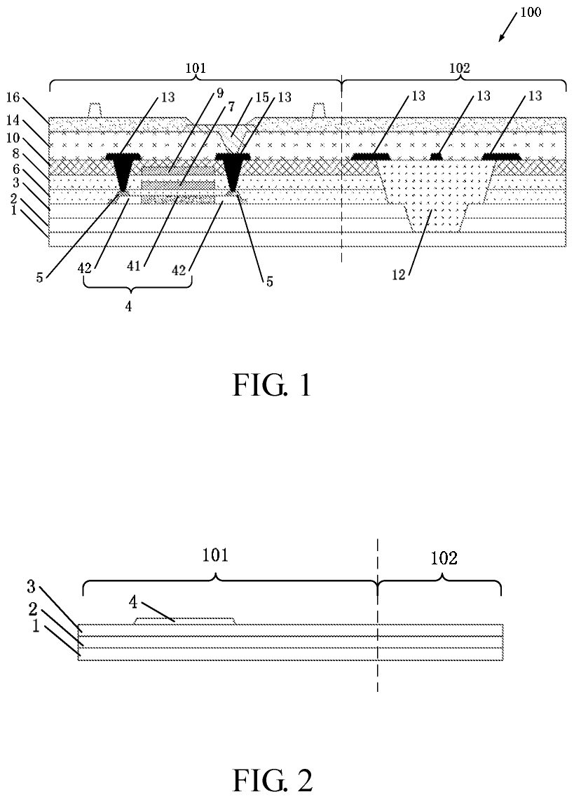

As illustrated in FIG. 1, the display panel 100 defines a display region 101 and a bending region 102 and includes a substrate 1, a first buffer layer 2, a second buffer layer 3, an active layer 4, a first source/drain electrode layer 5, an insulation layer, a gate electrode layer, an interlayer insulation layer 10, and a second source/drain electrode layer 11.

As illustrated in FIG. 1, the substrate 1 includes a first base, a middle layer, and a second base. Polyimide can be selected as a composition material of the first base and the second base, and the first base and the second base manufactured from the polyimide has good flexibility. A composition material of the middle layer can be SiO₂ and also can be SiNₓ, and further can be a staked structure of SiO₂ and SiNₓ. The middle layer manufactured from the composition material has water-oxygen proof property, and reliability between the first base and the second base can be improved.

As illustrated in FIG. 1, the first buffer layer 2 and the second buffer layer 3 are disposed on the substrate 1, which primarily serve as a buffer function and a protection function.

As illustrated in FIG. 1, the active layer 4 is disposed on the second buffer layer 3 of the display region 101. The active layer 4 includes a host section 41 and two lateral sections 42. Specifically, in this embodiment, primarily utilizing excimer laser crystallization technology to realize polysiliconization of the active layer 4, and then using a photoresist (PR) photomask to make the active layer 4 be patterned to form the host section 41 and the two lateral sections 42, and finally doping ions to the two lateral sections of the active layer 4 by one PR photomask to form a p-type semiconductor.

Specifically, in this embodiment, primarily utilizing excimer laser crystallization technology to realize polysiliconization of the active layer 4, and then using a photoresist (PR) photomask to make the active layer 4 be patterned to form the host section 41 and the two lateral sections 42, and finally doping ions to the two lateral sections 42 of the active layer 4 by one PR photomask to form a p-type semiconductor.

As illustrated in FIG. 1, the first source/drain electrode layer 5 and the active layer 4 are disposed on a same layer; the first source/drain electrode layer 5 includes a first source electrode and a first drain electrode; and the first source electrode and the first drain electrode respectively overlap on the two lateral sections 42 of the active layer 4. Specifically, part of the first source electrode and part of the first drain electrode are disposed on the second buffer layer 3, and other part of the first source electrode and other part of the first drain electrode overlap on the lateral sections 42 of the active layer 4. Because it is facilitated to improve abnormal phenomena such as voltage drop, brightness unevenness of light emitting, on the other hand, by reducing a photomask of a process for a planarization layer, the present disclosure prevents a phenomenon of film peeling during covering the top planarization layer after the bottom planarization layer is etched at a large area, thereby greatly improving reliability of the display panel 100.

As illustrated in FIG. 1, the insulation layer is disposed on the first source/drain electrode layer 5, and the gate electrode layer is disposed on the insulation layer. Specifically, the insulation layer includes a first insulation layer 6 and a second insulation layer 8; the gate electrode layer includes a first gate electrode layer 7 and a second gate electrode layer 9; the first insulation layer 6 is disposed on the active layer 4; the first gate electrode layer 7 is disposed on the first insulation layer 6; the second insulation layer 8 is disposed on the first gate electrode layer 7; the second gate electrode layer 9 is disposed on the second insulation layer 8.

As illustrated in FIG. 1, the interlayer insulation layer 10 is disposed on the gate electrode layer. Specifically, the interlayer insulation layer 10 is disposed on the second gate electrode layer 9.

As illustrated in FIG. 1, the display panel 100 further includes a second source/drain electrode layer 13. The second source/drain electrode layer 13 is disposed on the interlayer insulation layer 10. The second source/drain electrode layer 13 of the display region 101 is connected to the first source/drain electrode layer 5 by a first contact hole. The second source/drain electrode layer 13 is configured to be a reticular structure.

As illustrated in FIG. 1, an organic photoresist layer 12 is disposed on the substrate 1 of the bending region 102, and the second source/drain electrode layer 13 is disposed on the organic photoresist layer 12. The organic photoresist layer 12 is formed by etching from a surface of the interlayer insulation layer 10 of the bending region 102 away from the substrate 1 till a surface of the substrate 1 toward the interlayer insulation layer 10 by PR photomask technology to form a groove, and filling organic photoresist material in the groove to form an organic photoresist layer.

As illustrated in FIG. 1, the display panel 100 further includes a planarization layer 14, and the planarization layer is disposed on the interlayer insulation layer 10 and the organic photoresist layer 12.

As illustrated in FIG. 1, the display panel 100 further includes a pixel electrode layer 15 and a pixel definition layer 16. Furthermore, the pixel electrode layer 15 is disposed on the planarization layer 14 of the display region 101, and the pixel electrode layer 15 is connected to the second source/drain electrode layer 13 by a second contact hole; the pixel definition layer 16 is disposed on the planarization layer 14 on both sides of the pixel electrode layer 15.

In summary, on one hand, the display panel 100 provided by this embodiment is facilitated to improve abnormal phenomena such as voltage drop, brightness unevenness of light emitting, on the other hand, by reducing a photomask of a process for a planarization layer, the present disclosure prevents a phenomenon of film peeling during covering the top planarization layer that after the bottom planarization layer is etched at a large area, thereby improving reliability of the display panel 100.

### The Second Embodiment

This embodiment provides a manufacturing method of the display panel 100 related by the first embodiment.

As illustrated in FIG. 2, step S1, making an array substrate 100 to be manufactured define the display region 101 and the bending region 102, providing the substrate 1, and forming the first buffer layer 2 and the second buffer layer 3 on the substrate 1; and step S2, depositing the active layer 4 on the second buffer layer 3.

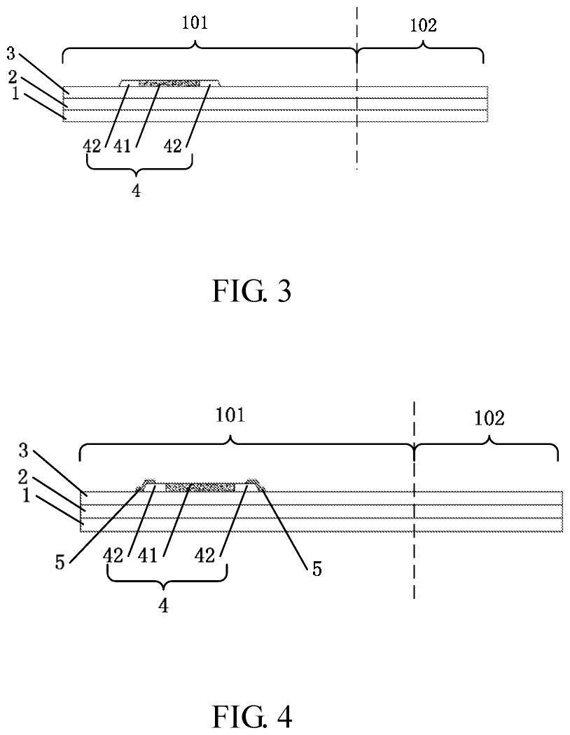

As illustrated in FIG. 3, step S3, utilizing excimer laser crystallization technology to realize polysiliconization of the active layer 4, and using a photoresist (PR) photomask to make the active layer 4 be patterned, doping ions to the active layer 4 by one PR photomask to form the host section 41 and the two lateral sections 42.

As illustrate in FIG. 4, step S4, depositing the first source/drain electrode layer 5 on the active layer 4, and using a photoresist (PR) photomask to realize patterning on the first source/drain electrode layer 5; etching all of the first source/drain electrode layer 5 of the bending region 102 to obtain the first source electrode and the first second drain electrode; and making the first source electrode and the second drain electrode overlap on the two lateral sections 42 of the active layer 4.

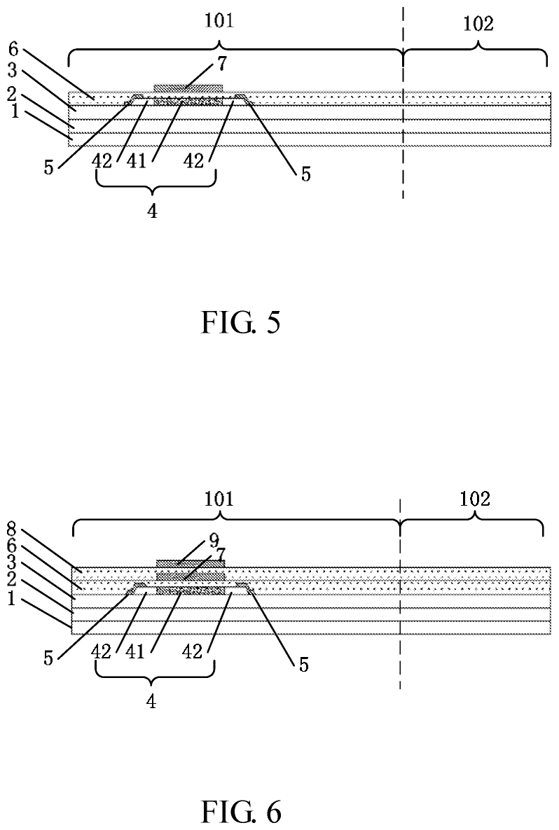

As illustrated in FIG. 5, step S5, depositing an insulation layer 6 on the first source/drain electrode layer 5, and depositing a gate electrode layer 7 on the insulation layer 6.

As illustrated in FIG. 6, in the step S5, further including depositing and manufacturing a second insulation layer 8 on the first gate electrode layer 7 and the first insulation layer 6, and depositing and manufacturing a second gate electrode layer 9 on the second insulation layer 8.

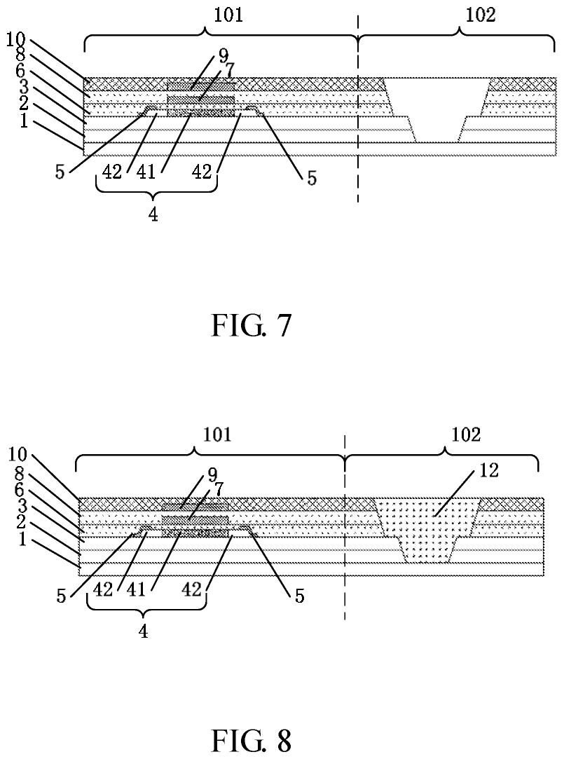

As illustrated in FIG. 7, step S6, depositing and manufacturing an interlayer insulation layer 10 on the second gate electrode layer 9 and the second insulation layer 8.

As illustrated in FIG. 7, step S7, etching from a surface of the interlayer insulation layer 10 of the bending region 102 away from the substrate 1 till a surface of the substrate 1 toward the interlayer insulation layer 10 by PR photomask technology to form a groove.

As illustrated in FIG. 8, the step S7 further includes using an organic photoresist material to fill the groove to form an organic photoresist layer 12.

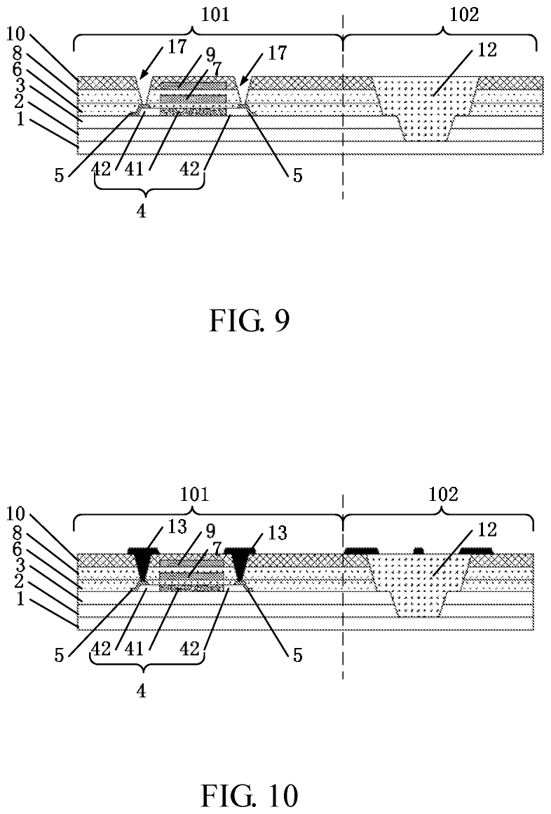

As illustrated in FIG. 9, the step S7 further includes forming a first contact hole 17 for connecting the first source/drain electrode layer 5 and the second source/drain electrode layer 13 on the display panel 100 of the display region 101 by one PR photomask process.

As illustrated in FIG. 10, the step S7 further includes: depositing and manufacturing the second source/drain electrode layer 13 on the interlayer insulation layer 10 and the organic photoresist layer 12, and the second source/drain electrode layer 13 is connected to the first source/drain electrode layer 5 by the first contact hole 17; by one PR photomask process to realize patterning to make the second source/drain electrode layer 13 be patterned into a reticular structure.

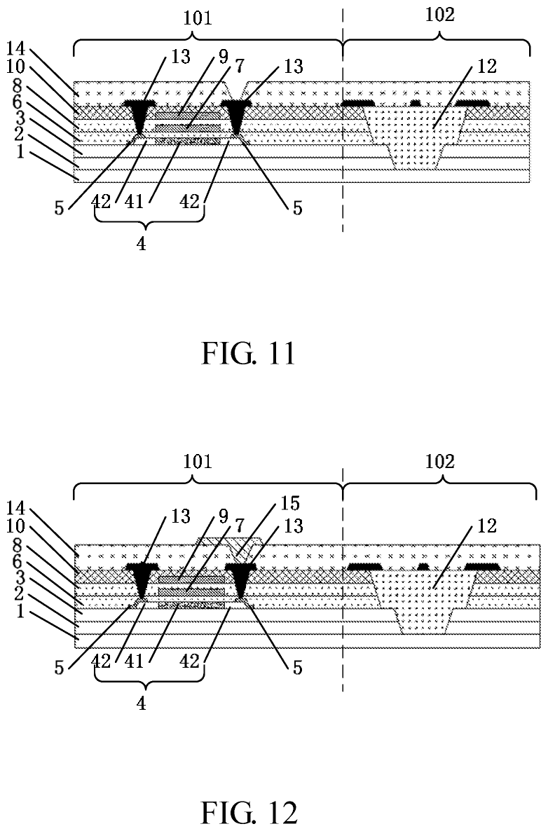

As illustrated in FIG. 11, step S8, depositing a planarization layer 14 on the second source/drain electrode layer 13, the interlayer insulation layer 10, and the organic photoresist layer 12, and forming a second contact hole for connecting the second source/drain electrode layer 13 and a pixel electrode layer 15 on the planarization layer 14.

As illustrated in FIG. 12, step S9, depositing the pixel electrode layer 15 on the planarization layer 14.

Furthermore, the step S9 further includes manufacturing a pixel definition layer 16 on the planarization layer 14 on both sides of the pixel electrode layer 15 to form the OLED display panel 100 as illustrated in FIG. 1.

In summary, the display panel provided by this embodiment is facilitated to improve abnormal phenomena such as voltage drop, brightness unevenness of light emitting, on the other hand, by reducing a photomask of a process for a planarization layer, the present disclosure prevents an abnormal phenomenon of film peeling during covering the top planarization layer after the bottom planarization layer is etched at a large area, thereby greatly improving reliability of the OLED display panel 100.

The array substrate and the manufacturing method, and the display panel provided by the present disclosure are described in detail above. It should be understood, that the exemplary embodiments described herein should be considered in descriptive, and is used for understanding the method of the present disclosure and its main idea, and is not intended to limit the present disclosure. Descriptions of features or aspects in each exemplary embodiment should generally be considered as being applied to similar features or aspects in other exemplary embodiments. While the present disclosure has been described with reference to the preferred embodiments, various modifications and changes can be made by those skilled in the art. The present disclosure is intended to cover such varieties and modifications within the scope of the appended claims, and any modifications, equivalents, and improvements made within the spirit and scope of the present disclosure should be included in the scope of the present disclosure.

What is claimed is:

1. An array substrate, defining a display region and a bending region, comprising:
a substrate;
a buffer layer disposed on the substrate;
an active layer disposed on the buffer layer of the display region, the active layer comprising a host section and two lateral sections; and
a first source/drain electrode layer comprising a first source electrode and a first drain electrode, the first source electrode and the first drain electrode respectively overlap on the two lateral sections of the active layer.

2. The array substrate as claimed in claim 1, comprising:
an insulation layer disposed on the first source/drain electrode layer;
a gate electrode layer disposed on the insulation layer;
an interlayer insulation layer disposed on the gate electrode layer; and
a second source/drain electrode layer disposed on the interlayer insulation layer, the second source/drain electrode layer connected to the first source/drain electrode layer by a first contact hole.

3. The array substrate as claimed in claim 2, wherein an organic photoresist layer is disposed on the substrate of the bending region, and the second source/drain electrode layer is disposed on the organic photoresist layer.

4. The array substrate as claimed in claim 2, wherein the insulation layer comprises a first insulation layer and a second insulation layer; the gate electrode layer comprises a first gate electrode layer and a second gate electrode layer; the first insulation layer is disposed on the active layer; the first gate electrode layer is disposed on the first insulation layer; the second insulation layer is disposed on the first gate electrode layer; the second gate electrode layer is disposed on the second insulation layer; the interlayer insulation layer is disposed on the second gate electrode layer.

5. The array substrate as claimed in claim 2, wherein the second source/drain electrode layer is configured to be a reticular structure.

6. A manufacturing method of manufacturing the array substrate as claimed in claim 1, comprising:
S1, making the array substrate to be manufactured define the display region and the bending region, providing the substrate, and forming the buffer layer on the substrate;
S2, depositing the active layer on the buffer layer;
S3, utilizing excimer laser crystallization technology to realize polysiliconization of the active layer, and using a photoresist (PR) photomask to make the active layer be patterned, doping ions to the active layer by one PR photomask to form the host section and the two lateral sections;
S4, depositing the first source/drain electrode layer on the active layer, and using a photoresist (PR) photomask to realize patterning on the first source/drain electrode layer; etching all of the first source/drain electrode layer of the bending region to obtain the first source electrode and the first drain electrode; and making the first source electrode and the first drain electrode overlap on two lateral sections of the active layer.

7. The manufacturing method of the array substrate as claimed in claim 6, comprising:
S5, depositing an insulation layer on the first source/drain electrode layer, and depositing a gate electrode layer on the insulation layer;
S6, depositing and manufacturing an interlayer insulation layer on the gate electrode layer;
S7, depositing and manufacturing a second source/drain electrode layer on the interlayer insulation layer, and the second source/drain electrode layer connected to the first source/drain electrode layer by a first contact hole.

8. The manufacturing method of the array substrate as claimed in claim 7, wherein in S7 comprises: etching from a surface of the interlayer insulation layer of the bending region away from the substrate till a surface of the substrate toward the interlayer insulation layer by PR photomask technology, and filling organic photoresist material in the groove to form an organic photoresist layer to form a groove; depositing the second source/drain electrode layer on the organic photoresist layer.

9. A display device, comprising a display panel, the display panel comprising:
an array substrate defining a display region and a bending region, wherein the array substrate comprises:
a substrate;
a buffer layer disposed on the substrate;
an active layer disposed on the buffer layer of the display region, the active layer comprising a host section and two lateral sections;
a first source/drain electrode layer comprising a first source electrode and a first drain electrode, the first source electrode and the first drain electrode respectively overlap on the two lateral sections of the active layer.

10. The display device as claimed in claim 9, wherein the array substrate comprises:
an insulation layer disposed on the first source/drain electrode layer;
a gate electrode layer disposed on the insulation layer;
an interlayer insulation layer disposed on the gate electrode layer; and
a second source/drain electrode layer disposed on the interlayer insulation layer, the second source/drain electrode layer connected to the first source/drain electrode layer by a first contact hole.

11. The display device as claimed in claim 10, wherein an organic photoresist layer is disposed on the substrate of the bending region, and the second source/drain electrode layer is disposed on the organic photoresist layer.

12. The display device as claimed in claim 10, the insulation layer comprises a first insulation layer and a second insulation layer; the gate electrode layer comprises a first gate electrode layer and a second gate electrode layer; the first insulation layer is disposed on the active layer; the first gate electrode layer is disposed on the first insulation layer; the second insulation layer is disposed on the first gate electrode layer; the second gate electrode layer is disposed on the second insulation layer; the interlayer insulation layer is disposed on the second gate electrode layer.

13. The display device as claimed in claim 10, wherein the second source/drain electrode layer is configured to be a reticular structure.

14. The display device as claimed in claim 11, wherein the display device comprises:
a planarization layer disposed on the interlayer insulation layer and the organic photoresist layer;
a pixel electrode layer disposed on the planarization layer of the display region, and the pixel electrode layer connected on the second source/drain electrode layer by a second contact hole; and
a pixel definition layer disposed on the planarization layer on both sides of the pixel electrode layer.
